(19) United States
(12) Patent Application Publication
(10) Pub. No.: US 2005/0095859 A1
(43) Pub. Date: May 5, 2005

(54) Precursor delivery system with rate control

(75) Inventors: Ling Chen, Sunnyvale, CA (US); Phillip Kang, Sunnyvale, CA (US); Seshadri Ganguli, Sunnyvale, CA (US)

Correspondence Address: MOSER, PATTERSON & SHERIDAN, LLP/;APPLIED MATERIALS, INC., 3040 POST OAK BOULEVARD, SUTIE 1500, HOUSTON, TX, 77056, US

(73) Assignee: APPLIED MATERIALS, INC.

(21) Appl. No.: 10/700,328

(22) Filed: Nov. 3, 2003

(51) Int. Cl. H01L 21/302; H01L 21/461

(52) U.S. Cl. 438/689

(57) ABSTRACT

A method and apparatus for a gas delivery system to deliver a precursor from a vessel to a process chamber via a process gas produced by flowing a first carrier gas into the vessel and combining with a second carrier gas flowing through a bypass around the vessel and a precursor monitoring apparatus disposed between the process chamber and the vessel. The precursor monitoring apparatus has a gas analyzer to generate a first signal indicative of a concentration of the precursor in the process gas or to a signal indicative of a flow rate of the process gas.

### BACKGROUND OF THE INVENTION

1. Field of the Invention

Embodiments of the present invention generally relate to semiconductor processing, and particularly to controlling precursor delivery to a semiconductor process chamber.

2. Description of the Related Art

As integrated circuit (IC) density increases, the need for greater uniformity and process control regarding layer thickness rises. The IC fabricators make aggressive demands on the semiconductor processing industry to develop fabrication tools that provide for larger production yields while increasing the uniformity of layers deposited on substrates having increasingly larger surface areas. In response to these demands, various technologies have been developed to deposit layers on substrates in a cost-effective manner, while maintaining control over the characteristics of the layer.

For example, chemical vapor deposition (CVD) is a common deposition process employed for depositing layers on a substrate by introducing reactive precursors into a process chamber and allowing the precursors to react with the substrate. A variant of CVD that is being explored for its potential to demonstrate superior layer uniformity is atomic layer deposition (ALD). ALD processes comprise sequential steps of physisorption or chemisorption monolayers of reactive precursor molecules on a substrate. A pulse of a first reactive precursor is introduced into a process chamber to deposit a first monolayer of molecules on the substrate. A pulse of a second reactive precursor follows to react with the first monolayer and form a product film. In this manner, a layer is formed on the substrate by alternating pulses of the appropriate reactive precursors into the process chamber. The cycle is repeated to form the layer to a desired thickness.

Both CVD and ALD techniques require precise control of reactive precursors introduced into the process chamber in order to produce a desired layer of uniform thickness. For some applications of CVD and ALD, one or more of the precursors come in the state of a solid or a liquid. Typically, the precursor changes state from a solid to a gas (vaporizes) at a certain pressure and temperature via a sublimation process carried out within a storage vessel. The precursor is delivered to the process chamber via a process gas produced by flowing a carrier gas through the vessel. The process gas comprises the vaporized precursor mixed with the carrier gas. The rate of sublimation depends on a temperature of the precursor, a surface area of the precursor and how the carrier gas flows through the vessel, each of which may be very difficult to control. Accordingly, it is often difficult to deliver a predictable amount of the precursor to the process chamber.

The difficulty in delivering a predictable amount of the precursor to the process chamber may lead to a number of problems. One problem is that irregularities in the amount of solid precursor delivered to the process chamber may result in non-uniformities in film thickness that adversely affects wafer quality and acceptability. This problem is addressed in co-pending, commonly assigned U.S. patent application Ser. No. 10/200,613, entitled, “Method and Apparatus for Monitoring Solid Precursor Delivery”, filed on Jul. 22, 2002.

The '613 patent application teaches that precursor delivery can be controlled by fluctuating the carrier gas flow, such that increasing the carrier flow increases the amount of delivered precursor or decreasing the carrier flow decreases the amount of delivered precursor. However, by fluctuating the carrier gas flow to maintain a constant precursor concentration, the flow rate across the substrate and the chamber pressure will vary in relation to the carrier gas flow. This flow rate and pressure differential can cause problems to the deposition process, such as surface irregularities. Furthermore, the thickness uniformity of a substrate surface is affected by not having independent control over the precursor delivery and the flow rate.

Therefore, a need exists for an improved method and apparatus for monitoring and adjusting the delivery of precursor and carrier gas flow to a processing chamber.

### SUMMARY OF THE INVENTION

In one embodiment, the present invention generally is an apparatus for controlling delivery of a precursor from a vessel to a process chamber. The apparatus comprises a first valve to regulate a first carrier gas flowing through an input into the vessel, an output from the vessel in fluid communication with the process chamber, a second valve to regulate a second carrier gas flowing to the process chamber. A process gas comprises the carrier gas, the second carrier gas and the precursor. A gas analyzer having an ultrasonic transducer generates a first signal indicative of a concentration of the precursor in the process gas. The apparatus also comprises a flow meter to generate a second signal indicative of a volume flow rate of the process gas and a controller configured to calculate a mass flow rate of the precursor based on the first and second signals.

In another embodiment, the present invention generally is a system comprising a process chamber, a gas delivery system to deliver a precursor from a vessel to the process chamber via a process gas produced by flowing a first carrier gas into the vessel and combining with a second carrier gas flowing through a bypass around the vessel. A precursor monitoring apparatus is disposed between the process chamber and the gas delivery system. The precursor monitoring apparatus has a gas analyzer to generate a first signal indicative of a concentration of the precursor in the process gas and an integral controller to receive the first signal and a second signal indicative of a volume flow rate of the process gas. The integral controller is configured to calculate a mass flow rate of the precursor based on the first and second signals.

In another embodiment, the present invention generally is an apparatus for delivering of a precursor from a vessel to a process chamber via a process gas. The apparatus comprises a first valve to regulate a first carrier gas flowing through an input into the vessel, an output from the vessel in fluid communication with the process chamber, a second valve to regulate a second carrier gas flowing to the process chamber. The process gas comprises the carrier gas, the second carrier gas and the precursor. A gas analyzer generates a first signal indicative of a concentration of the precursor in the process gas, and a controller receives the first signal and a second signal indicative of a volume flow rate of the process gas flowing into the process chamber. The controller is configured to maintain the concentration of the precursor and the volume flow rate of the process gas constant by adjusting the first valve and the second valve.

In another embodiment, the present invention generally is a method for monitoring and controlling delivery of a precursor from a vessel to a process chamber. The method comprises measuring a concentration of the precursor in a process gas, wherein the process gas is produced by flowing a first carrier gas into the vessel and combining with a second carrier gas, measuring a volume flow rate of the process gas and calculating a mass flow rate of the precursor based on the measured concentration of the precursor in the process gas and the measured volume flow rate of the process gas.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates an embodiment of a semiconductor processing system having a precursor delivery system;

FIG. 2 illustrates another embodiment of a semiconductor processing system having a precursor delivery system;

FIG. 3 is a flow diagram illustrating exemplary operations of a method for precursor delivery according to one embodiment; and

FIGS. 4-6 illustrate other embodiments of a semiconductor processing system having a precursor delivery system;

### DETAILED DESCRIPTION OF THE PREFERRED EMBODIMENT

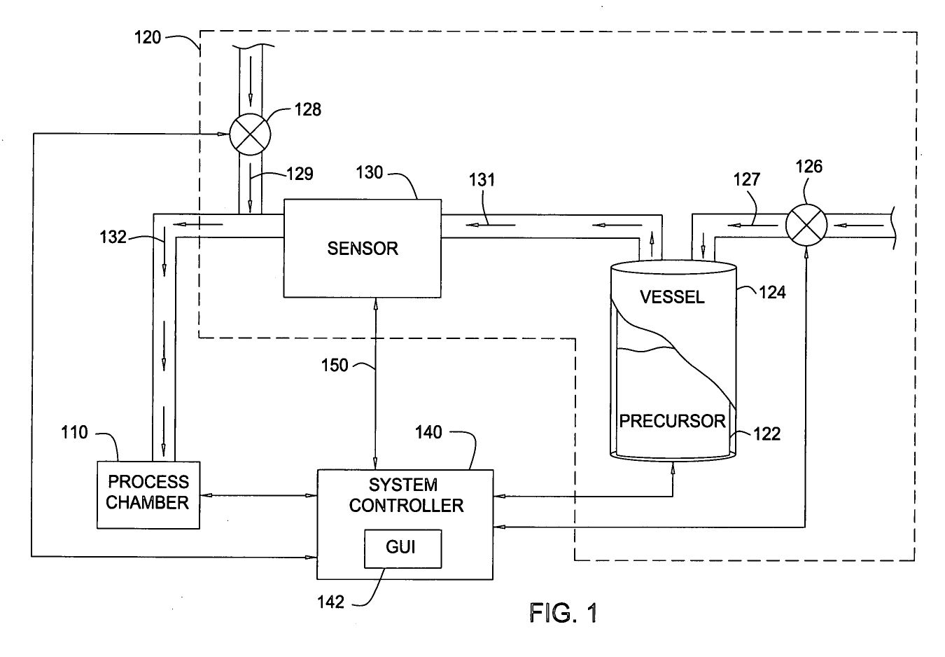

FIG. 1 illustrates an exemplary semiconductor processing system including a process chamber 110, a gas delivery system 120 and a sensor 130. The process chamber 110 may be any suitable semiconductor process chamber, such as a chemical vapor deposition (CVD) chamber, atomic layer deposition (ALD) chamber, plasma enhanced chemical vapor deposition (PECVD) chamber or etch chamber. Examples of suitable process chambers include, but are not limited to, the PRODUCER® series of CVD chambers, the SPRINT® and ENDURA® series of CVD/ALD chambers and the CENTURA® series of etch chambers, available from Applied Materials, Inc. of Santa Clara, Calif.

The gas delivery system 120 transports a precursor 122 from a vessel 124 to the process chamber 110 via a process gas. Typically, the precursor 122 changes state from a solid to a gas (or vapor) in the vessel 124 by a sublimation process or the precursor 122 changes from a liquid to a gas by an evaporation process in the vessel. The precursor 122 may have a gas or fluid state. The vaporization process (i.e., sublimation or evaporation) for the precursor 122 may be initiated by any suitable well-known technique. For example, the precursor 122 may be heated to a predetermined temperature or mixed with a bubbling liquid within the vessel 124. For some embodiments, the temperature of the vessel 124 may be controlled in an effort to regulate the vaporization process. Further description for controlling the temperature of the precursor within a vessel via a gradient temperature is in the commonly assigned U.S. patent application Ser. No. 10/447,255, entitled “Method and Apparatus of Generating PDMAT Precursor”, filed on May 27, 2003, and is herein incorporated by reference. The vessel and the precursor are maintained in a temperature range from about 25° C. to about 600° C., preferably in the range from about 50° C. to about 150° C.

A carrier gas 127 flows through a valve 126 into the vessel 124 and mixes with the vaporized precursor 122 to form the precursor gas 131. The precursor gas 131 flows out of the vessel 124 and transports the vaporized precursor 122 to the process chamber 110 via the sensor 130 (e.g., ultrasound or FT-IR). Also, a carrier gas 129 flows through a valve 128 and combines with precursor gas 131, but by-passes the vessel 124. Therefore, carrier gas 127, precursor 122 and carrier gas 129 combine to form process gas 132. Also, carrier gas 129 can flow directly to and be useful during purge cycles of the process chamber 110.

The type of precursor 122 may be chosen based on the particular process to be performed in the process chamber 110. For example, the precursor 122 may be a metal organic compound, such as tungsten carbonyl (W(CO)₆), to deposit a metal film on a wafer. As another example, the precursor 122 may be (Me₂N)₅Ta (PDMAT) to form a film comprising tantalum (e.g., Ta or Ta₃N₅). As other examples, the precursor 122 may also be a precursor to deposit a layer of dielectric material on the wafer or xenon difluoride (XeF₂), for example, to deliver fluorine to an etch chamber. Other compatible precursors to embodiments of the invention include (Et₂N)₅Ta (PDEAT), (^{t}BuN)Ta(NMe₂)₃ (TBTDMT), (^{t}BuN)Ta(NEt₂)₃ (TBTDET), TaCl₅, TaF₅, (MeO)₅Ta, TiCl₄, (ⁱPrO)₄Ti, Ni(CO)₄, Cp₂Ru, (EtCp)₂Ru, HfCl₄, (Et₂N)₄Hf (TDEAH) and (Me₂N)₄Hf.

The carrier gases 127 and 129 are typically chosen based on the precursor 122. For example, argon may be chosen as the carrier gas if the precursor 122 is tungsten carbonyl. The carrier gases or purge gases may be an inert gas, such as argon, helium or nitrogen, and may be reactive or non-reactive with the precursor 122. Hydrogen is a suitable carrier gas or purge gas in some embodiments of the invention.

To facilitate understanding, the gas delivery system 120 is illustrated as delivering only one gas to the process chamber 110. However, the gas delivery system 120 may deliver additional gases (i.e., carrying additional precursors) to the process chamber 110 and multiple gas delivery systems are also contemplated. While valve 126 controls the flow of carrier gas 126, valve 128 controls the flow of carrier gas 129. The carrier gases 127 and 129 can be the same or different gases. In a preferred embodiment, the carrier gases 127 and 129 are the same, such as argon. In one aspect, carrier gases 127 and 129 originate from the same source or tank. However, in another embodiment, carrier gases 127 and 129 are different, such as carrier gas 127 is argon and carrier gas 129 is hydrogen. It will also be appreciated by those skilled in the art that the gas delivery system 120 may also comprise additional components not illustrated, such as bypass valves, purge valves, flow controllers, and/or temperature controllers. As used herein, a bypass is a conduit adapted around the solid precursor and permits a carrier gas or purge gas to bypass or flow pass the vessel 124, therefore bypassing the solid precursor while flowing to the process chamber 110.

The vessel 124 may be any suitable container, for example, capable of withstanding the pressure and temperature required to vaporize the precursor 122. For some embodiments, the container may comprise a bubbler, well known in the art. Besides these system conditions, the vessel 124 is made from a material that is non-reactive to the precursor. Suitable materials to manufacture the vessel 124 include steel (e.g., stainless), aluminum, aluminum alloy or nickel, amongst others. The vessel 124 may contain a lining to enhance the chemical protection, such as PTFE, nickel, magnesium fluoride or glass. In one aspect, vessel 124 is an ampoule, such as described in commonly assigned U.S. patent application Ser. No. 10/198,727, entitled, “Method and Apparatus for Providing Gas to a Processing Chamber”, filed on Jul. 27, 2002, and U.S. patent application Ser. No. 10/208,305, entitled, “Method and Apparatus for Providing Gas to a Processing Chamber”, filed on Jul. 29, 2002, both herein incorporated by reference.

However, embodiments of the present invention utilize the sensor 130 to calculate a mass flow rate of precursor 122 being delivered to the process chamber 110 based on measured precursor densities or concentrations and measured volume flow rates of the process gas. As used herein, mass flow rate refers to a mass amount per unit time of precursor 122 flowing from the vessel 124, volume flow rate refers to a volume per unit time of process gas flowing from the vessel 124 and precursor density or precursor concentration refers to a mass of precursor material in a given volume of the process gas. It should be noted that the sensor 130 is used to monitor delivery of precursor material in a process gas, whereas the precursors are generally solid or liquid at ambient temperature and/or pressure. Upon vaporizing, the precursors have more fluid characteristics, such as a gas.

As illustrated, the sensor 130 is disposed in-line with the process gas flow between the vessel 124 and the process chamber 110. For other embodiments, the sensor 130 may be disposed between a gas delivery system and a reservoir (not shown). For example, the reservoir may be filled with the precursor gas 131 containing the precursor 122. In another embodiment, a reservoir is prior to the process chamber 110 and may be filled with process gas 132. This latter embodiment could be used to insure mixing of the precursor 122 with additional carrier gas being delivered via valve 128. In either of the aforementioned embodiments, the precursor 122 may then be delivered from the reservoir to the process chamber 110.

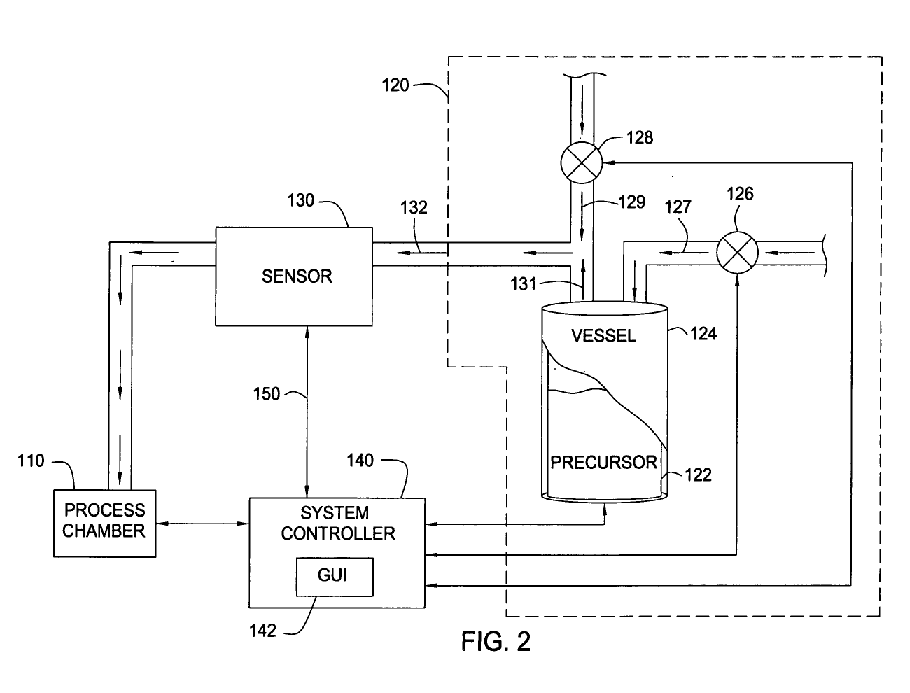

FIG. 2 illustrates an embodiment whereas carrier gas 129 is controlled with valve 128 and incorporated into the delivery system 120. Therefore, as the precursor gas 131 exits the vessel 124, carrier gas 129 combines with precursor gas 131 to form process gas 132. The process gas 132 flows to the process chamber 110 via the sensor 130.

In either FIG. 1 or 2, the sensor 130 may be any suitable instrument and/or technique capable of analyzing the gas and generating a signal indicative of the precursor concentration or density. Exemplary techniques include, but are not limited to, measuring concentration with ultrasonic transducers, infrared spectroscopy (e.g., FT-IR), ultraviolet spectroscopy (e.g., UV-vis), gas chromatography (GC), mass spectroscopy (MS) and combinations thereof. Ultrasonic transducers may be particularly well suited for precursor density analysis due to a high sensitivity in detecting material components in a gas. Sensor 130 may also be a mass flow meter to measure the mass of the precursor. A mass flow meter measures the process gas rate (sum of carrier gas and precursor flow rates) and deduces the flow of the precursor by subtracting the carrier gas flow rate from the measured process gas rate flowing through the pipeline.

In an ALD process, the dosage of a precursor may be delivered to the chamber in a range with a high valve (e.g., 300 sccm) and a low value (e.g., 50 sccm). If the dosage flowing to the chamber is very high, the subsequent purge step may not be effective to purge the precursor from the reaction space to the required partial pressure to prevent gas phase reaction with reactant gas. However, the dosage of the precursor has to be high enough to deposit a monolayer of the precursor adsorbed on the substrate. In an ALD process, the control mechanism may be required to keep the dosage of the precursor within the acceptable band.

In ALD process, the flow of a precursor to the chamber is pulsed, which causes adiabatic expansion and cooling of the precursor and carrier gas molecules. Therefore, the concentration of a precursor measured by the ultra-sound sensor or FTIR spectroscopy will vary with the phase of the cycle. In case of an ultrasound sensor, the measured concentration variation during any phase of a cycle is dependent on the total pressure fluctuation during a cycle, the molecular weight of the precursor and carrier gas and their specific heat capacity. The measured concentration during a cycle may vary depending on the precursor and carrier gas molecules while different techniques may be adopted to get a more consistent concentration value. In one example, the controller of the sensor is synchronized with the opening of the precursor valve to the chamber, and the concentration value is only recorded when the valve is open. In another example, the measured concentration data is averaged over the entire wafer to calculate the dosage to the wafer. In another example, before or after a process, the ampoule and the gas line with the sensor may be pressurized to a pre-determined value with the precursor PLC valve closed. The concentration of the precursor may be measured with stagnant flow. In a typical ALD process, the minimum and maximum dosage limit values are such that dosage control during a process is not required. Control actions or control adjustments may be implemented if a cycle trend shows dosages calculated per substrate are increasing or decreasing and may extend outside the allowable limits.

In one aspect, an ultrasound transducer is a preferred instrument while using the system of FIG. 1 in a CVD application. In another aspect, an ultrasound transducer or a mass flow meter is a preferred instrument while using the system of FIG. 2 in a CVD application. The valves 126 and 128 determine the flow rate of carrier gases 127 and 129, respectively. Therefore, the flow rate of precursor 122 can be determined by subtracting the flow rates of carrier gases 127 and 129 from the measured flow rate of process gas 132.

Regardless of the measurement technique, the sensor 130 generates a signal on connection 150 coupled with the system controller 140. The second signal may be an analog signal, a serial communications signal (e.g., RS-232 or RS-485) or a well-known industrial protocol bus signal, such as the General Purpose Interface Bus (GPIB) signal. The system controller 140 may be any suitable controller capable of calculating a mass flow rate of the precursor 122 based on the signals generated by the sensor 130. For some embodiments, the system controller 140 may be a programmable logic controller (PLC) or a rack-mounted personal computer (PC). The system controller 140 may comprise a central processing unit (CPU), memory and interface circuitry. The CPU may be one of any form of computer processor that can be used in an industrial setting. The memory may be one or more of readily available computer-readable medium, such as random access memory (RAM), read only memory (ROM), floppy disk, hard disk or any other form of digital storage, local or remote.

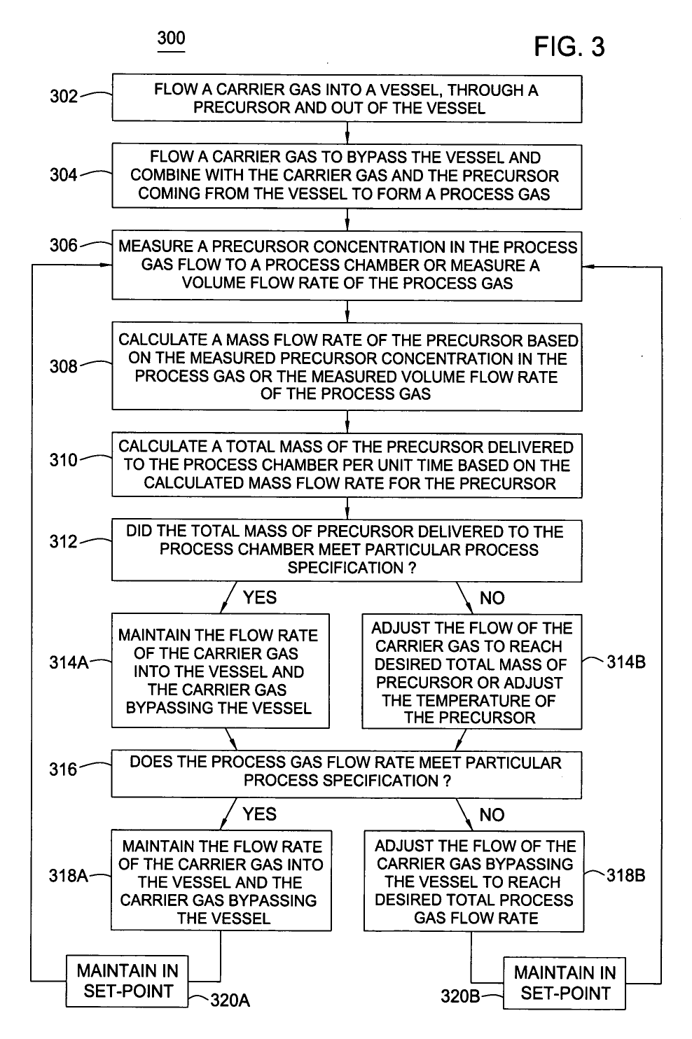

FIG. 3 is a flow diagram illustrating exemplary operations of a method 300 for delivering a precursor to a process chamber. The method 300 is generally stored in the memory as a software routine. Although the method 300 is discussed as being implemented as a software routine, some of the method steps that are disclosed therein may be performed in hardware as well as by the system controller 140. The operations of FIG. 3 are described with reference to the embodiment illustrated in FIG. 2 while initiating a process set-point.

The process 300 begins at step 302, by flowing a carrier gas 127 (e.g., Ar, N₂, He or H₂) into a vessel 124 via the valve 126. The system controller 140 controls valve 126, which in turn adjust the carrier gas flow into the vessel 124. The carrier gas 127 has a flow rate in the range from about 10 sccm to about 5,000 sccm, preferably from about 50 sccm to about 1,000 sccm. The carrier gas 127 combines with the precursor and exits the vessel as the precursor gas 131.

In step 304, a flow of carrier gas 129 (e.g., Ar, N₂, He or H₂) bypasses the vessel 124 and is controlled by valve 128. The carrier gas 129 has a flow rate in the range from about 10 sccm to about 5,000 sccm, preferably from about 50 sccm to about 1,000 sccm. The combining of carrier gases 127 and 129 and the precursor 122 forms a process gas 132 with a flow rate in the range from about 10 sccm to about 5,000 sccm, preferably from about 50 sccm to about 1,000 sccm.

At step 306, a concentration or density of the precursor 122 in a process gas 132 is measured while flowing to a process chamber 110. For example, the system controller 140 reads the signal generated by the sensor 130 via connection 150. Generally, sensor 130 is an ultrasound transducer or a mass flow meter. Alternatively during step 306, a volume flow rate of the process gas 132 is measured. For example, the system controller 140 may read the signal generated by the sensor 130, wherein the sensor 130 is a mass flow meter. The interface circuitry may comprise any combination of analog to digital (A/D) converters, digital signal processing (DSP) circuits and communications circuits required to convert the first and second output signals to a format suitable for use by the CPU 210.

The operations of step 306 may be performed in any order and may be performed simultaneously. The precursor concentration or density and process gas volume flow rate may also be measured once, or several times, for a process cycle. For example, the precursor concentration may be measured M times for a process cycle, while the process gas volume flow rate is measured N times for a process cycle, with M and N comprising integers. Further, the mass flow rate of the precursor 122 may not be measured every process cycle, for example, if the mass flow rate of the precursor 122 does not change rapidly with respect to the process cycle. A process cycle refers to a duration the precursor 122 is delivered by the process gas to the process chamber 110.

During step 310, the mass flow rate of the precursor is calculated based on the measured precursor concentration in the process gas or by the measured volume flow rate of the process gas. A total mass of precursor delivered to the process chamber 110 per unit time is based on the calculated mass flow rate for the precursor during step 312. For a detailed formulation explanation, as used in steps 310 and 312, see co-pending, commonly assigned U.S. patent application Ser. No. 10/200,613, entitled, “Method and Apparatus for Monitoring Solid Precursor Delivery”, filed on Jul. 22, 2002, which is hereby incorporated by reference.

The precursor 122 is delivered in a controlled fashion to the process chamber 110, as postulated in step 312. Semiconductor processes (e.g., deposition or etch) generally need accurate delivery of the precursor 122. In one embodiment of this invention, if the mass of the precursor 122 delivered to the process chamber 110 is acceptable within the tolerance of the semiconductor process, then the process conditions should be kept constant. That is, the temperature of the vessel 124 and the setting for valves 126 and 128 should be maintained by the system controller 140 so that the total flow rates of carrier gases 127 and 129 will stay constant, as described in step 314A.

However, in another embodiment of the invention, such as step 314B, if the mass of the precursor delivered to the process chamber is outside the tolerance of the semiconductor process, then the process conditions are adjusted. That is, the temperature of the vessel 124 and the setting for valves 126 and 128 are adapted while the flow rates of carrier gases 127 and 129 usually stay constant.

The mass of the precursor delivered may become too low. In this case, the temperature of the vessel 124 is increased, assuming the precursor vaporizes without decomposing. Also, increasing the amount valve 126 is opened increases the flow rate of carrier gas 127. Therefore, the vaporization process is faster and the precursor concentration increases. A combination of increased temperature and total flow rate may be beneficial in some protocols.

Also, the mass of the precursor delivered may become too high. In this case, the temperature of the vessel 124 is decreased, assuming the precursor will still vaporize at the lower temperature. Also, decreasing the amount valve 126 is opened decreases the flow rate of carrier gas 127. Therefore, the vaporization process is slower and the precursor concentration decreases. Furthermore, a combination of decreased temperature and flow rate may be beneficial in some protocols.

The amount of precursor 122 inside vessel 124 proportionally affects the level at which the carrier gas is saturated with precursor. For example, if the surface area of a solid precursor within the vessel increases, the rate of precursor evaporation will also increase. Therefore, the level of precursor saturation increases. Likewise, if the surface area of a solid precursor within the vessel decreases, the rate of precursor evaporation and the precursor saturation will also decrease. Similar, as the height of a liquid precursor within the vessel decreases, the rate of precursor evaporation and the precursor saturation will decrease.

Once the correct total mass of precursor is delivered to the process chamber 110, step 316 poses the question of whether the flow of process gas 132 is acceptable within the process specifications. In one embodiment, step 318A describes maintaining the correct flow of process gas 132 within the tolerance to the process specifications. Valves 126 and 128, as well as the flow of carrier gases 127 and 129, are kept at the same setting to maintain the constant delivery of process gas 132 to the process chamber 110.

However, in another embodiment of the invention, such as step 318B, if the flow of process gas 132 delivered to the process chamber is outside the tolerance of the semiconductor process, then the flow of carrier gas 129 should be adjusted, while the flow of carrier gas 127 and the temperature of vessel 124 remains constant. In one aspect, the flow of carrier gas 129 is too low. In this case, increasing the amount valve 128 is opened will increase the flow of carrier gas 129. Therefore, the flow of process gas 132 will be faster. In another aspect, the flow of carrier gas 129 is too high. In this case, decreasing the amount valve 128 is opened will decrease the flow of carrier gas 129. Therefore, the flow of process gas 132 will be slower.

Initially, steps 302-318 are followed to achieve the set-point, i.e., by reaching steps 318A or 318B, the parameters for the subsequent process have been reached. Steps 320A or 320B are included to monitor and maintain the set-point with the correct parameters. The set-point insures consistent delivery of the precursor to each substrate being processed in the process chamber 110.

Referring to FIG. 1, for some embodiments, the sensor 130 may communicate some or all of the calculated parameters (e.g., mass flow rate or total mass) to an external device. For example, the sensor 130 may communicate with a system controller 140 through a connection 150. The connection 150 may comprise any suitable interface, such as a serial communications interface (e.g., RS-232 or RS-485) or a well-known bus interface, such as the General Purpose Interface Bus (GPIB). The system controller 140 may be any suitable controller capable of monitoring and regulating the processes performed in the process chamber 110. Though not shown, heaters and thermocouples may be included as part of the gas delivery system 120, sensor 130 and/or the gas lines thereof and are managed by the system controller 140.

The system controller 140 may display information received from the sensor 130 on a graphical user interface (GUI) 142. For example, the system controller 140 may display any one, or all of, a mass flow rate for the precursor 122, an amount of precursor 122 remaining in the vessel 124, flow rate for process gas 132 or settings for valves 126 and 128. Further, the system controller 140 may be configured to generate an alarm message and/or an alarm output, for example, when an amount of the remaining precursor 122 falls below a threshold amount. The alarm message and/or alarm output may prompt an operator to replenish or replace the precursor 122.

The system controller 140 may also use the information received from the sensor 130 as feedback to control delivery of the precursor 122 to the process chamber 110 in an attempt to maintain a target mass flow rate for the precursor 122 or a constant flow of process gas 131. For example, the system controller 140 may compare a calculated mass flow rate received from the sensor 130 to the target mass flow rate. In response to the comparison, the system controller 140 may attempt to adjust the mass flow rate of the precursor 122 by varying a temperature in the vessel 124 via a temperature controller to control the sublimation rate or by varying a volume flow rate of the carrier gas 127 into the vessel 124 by adjusting a valve 126. In order to maintain a constant flow of process gas 132, upon adjusting valve 126, valve 128 will also be adjusted to control the flow of carrier gas 129.

In one embodiment, valve 126 is adjusted such that the flow of carrier gas 127 increases so that the mass flow rate of the precursor 122 also increases. In order to maintain a constant flow of process gas 132, valve 128 is adjusted to decrease the flow of carrier gas 129. In another embodiment, valve 126 is adjusted such that the carrier gas 127 flow decreases so that the mass flow rate of the precursor 122 also decreases. In order to maintain a constant flow of process gas 132, valve 128 is adjusted to increase the flow of carrier gas 129.

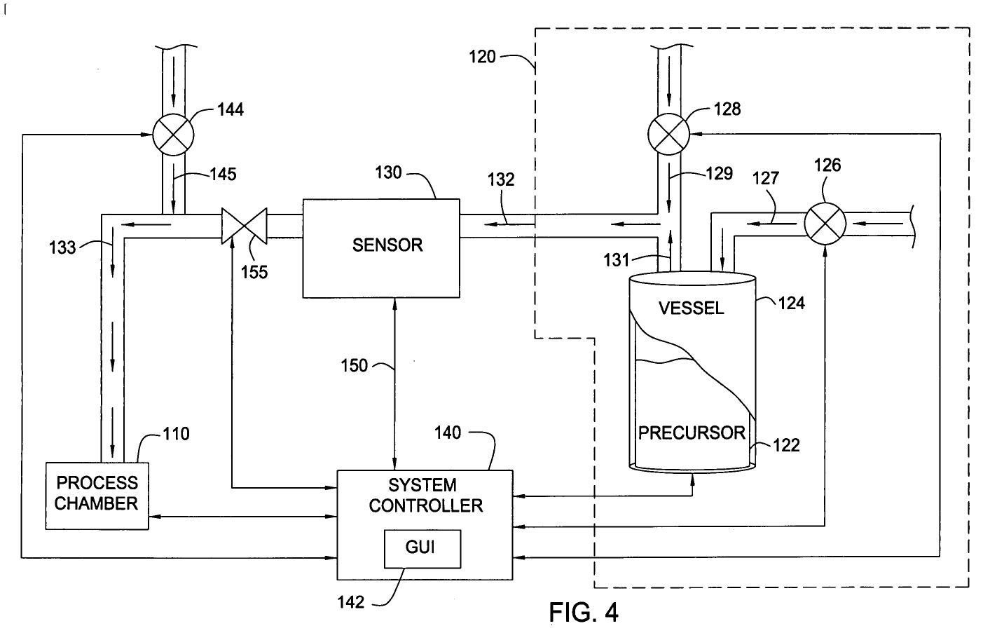

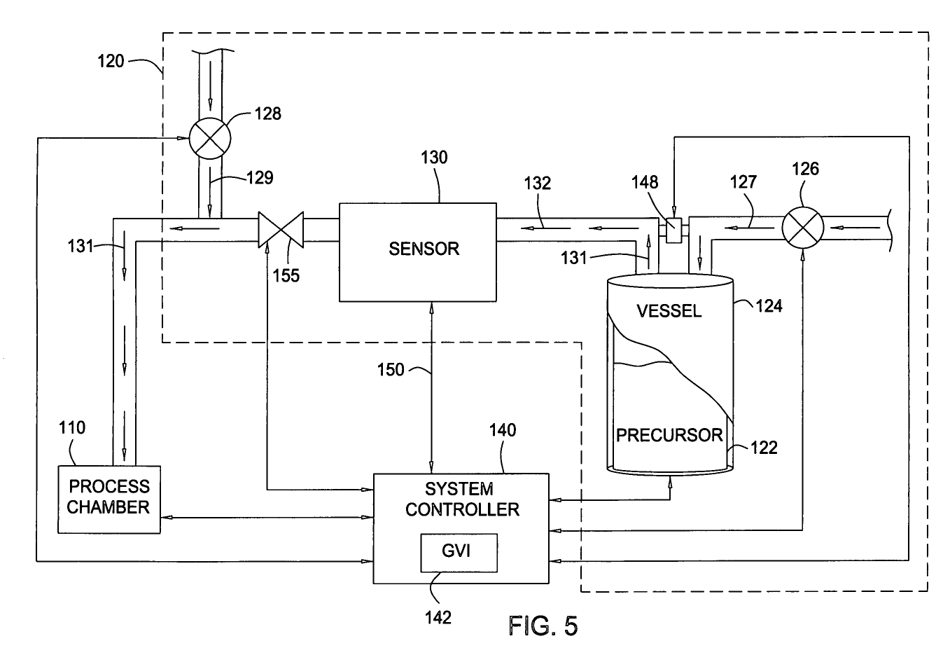

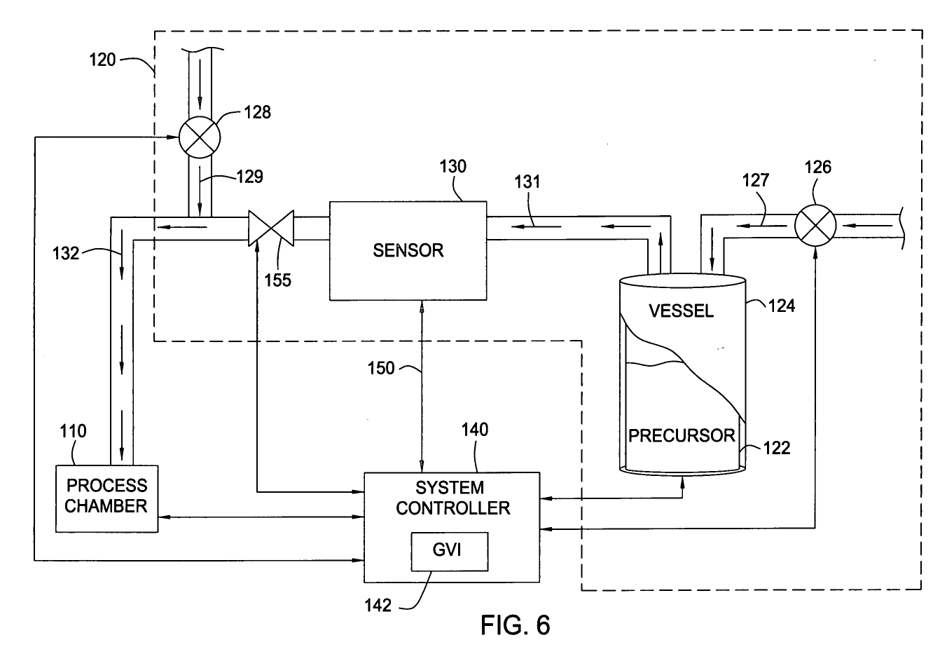

FIGS. 4-6 depict various embodiments of the invention. These embodiments could be used for during CVD techniques, but are preferably used during ALD techniques. Further description of ALD techniques are described in the co-pending, commonly assigned U.S. Patent Publication No. 20020106846, entitled, “Formation of Tantalum Nitride Layer”, filed on Feb. 2, 2001, which is hereby incorporated by reference. A programmable logic controller (PLC) 155 allows dispersal by pulsing precursor gas 131 or process gas 132 towards the process chamber 110. In one embodiment of FIG. 4, PLC 155 pulses process gas 132 into a flow of carrier gas 145. Carrier gas 145 is controlled by valve 144. A dilute process gas 133 is formed as process gas 132 combines with carrier gas 145. An embodiment of FIG. 5 depicts a metering valve 148. Metering valve 148 permits a portion of carrier gas 127 to bypass the vessel 124 and dilute precursor gas 131 while forming process gas 132. A dilute process gas 133 if formed as process gas 132 is pulsed via PLC 155 and combined into carrier gas 129.

Controlling delivery of the precursor 122 and maintaining a constant gas flow to the process chamber 110 may be particularly challenging for ALD process, because the process gas is delivered in short duration pulses. For example, the system controller 140 may generate the short duration pulses via pneumatically controlled (0.5 s) or electrically controlled (0.2 s) valves, such as PLC 155. Some PLC valves useful for this invention are described in commonly assigned U.S. patent application Ser. No. 10/199,482, entitled, “Valve Design and Configuration for Fast Delivery System”, filed on Jul. 19, 2002, and is herein incorporated by reference. The valves may allow passage of the precursor to the chamber by pulsing at a rate from about 0.01 second to about 5 seconds, preferably from about 0.05 second to about 3 seconds and more preferably from about 0.1 to about 2 seconds.

In some embodiments, the sensor 130 may determine an amount of precursor 122 delivered on each pulse and communicate the information to the system controller 140. The system controller 140 may, for example, determine if an adequate amount of precursor 122 was delivered on a particular pulse and, if not, increase the length of time for the pulse, or pulses, until an adequate amount has been delivered. As previously described, the amount of precursor 122 delivered on each pulse may be accumulated to ensure the amount of precursor 122 delivered to a wafer during a process cycle is within a predetermined range. The system controller 140 may generate additional pulses to ensure a consistent amount of precursor 122 is delivered for each wafer.

In one example, the set-point was initiated to deliver precursor to a 200 mm ENDURA® series TaN ALD chamber, available from Applied Materials, Santa Clara, Calif. Argon, as a carrier gas, is passed through the vessel (e.g., ampoule) and also through the bypass of the vessel with a combined and controlled rate in a range from about 50 sccm to about 300 sccm, preferably about 100 sccm. The vessel and the precursor (e.g., PDMAT) is maintained with a temperature in a range from about 60° C. to about 75° C., preferably at about 68° C. A purge gas, such as argon, could be injected into the process chamber with a rate in a range from about 500 sccm to about 3,000 sccm, preferably about 1,250 sccm. While maintaining the set-point, the amount of purge gas is decreased by the amount the combined carrier gases are increased. The process containing the PDMAT is pulsed into the chamber at a range from about 0.25 second to about 1.5 second, preferably at about 0.5 second.

In another example, the set-point was initiated to deliver precursor to a 300 mm ENDURA® series TaN ALD chamber, available from Applied Materials, Santa Clara, Calif. Argon, as a carrier gas, is passed through the vessel (e.g., ampoule) and also through the bypass of the vessel with a combined and controlled rate in a range from about 100 sccm to about 1,000 sccm, preferably about 500 sccm. The vessel and the precursor (e.g., PDMAT) is maintained with a temperature in a range from about 60° C. to about 75° C., preferably at about 70° C. A purge gas, such as argon, could be injected into the process chamber with a rate in a range from about 1,000 sccm to about 5,000 sccm, preferably about 3,000 sccm. While maintaining the set-point, the amount of purge gas is decreased by the amount the combined carrier gases are increased. The process containing the PDMAT is pulsed into the chamber at a range from about 0.5 second to about 1.5 second, preferably at about 1.0 second.

While the foregoing is directed to embodiments of the present invention, other and further embodiments of the invention may be devised without departing from the basic scope thereof, and the scope thereof is determined by the claims that follow.

1. An apparatus for controlling delivery of a precursor from a vessel to a process chamber, comprising:
a first valve adapted to regulate a first carrier gas flowing into the vessel, whereby the first carrier gas is combined with the precursor;
an output from the vessel in fluid communication with the process chamber;
a second valve adapted to regulate a second carrier gas flowing to the process chamber whereby the first and second carrier gases and the precursor are combined to form a process gas;
a gas analyzer having an ultrasonic transducer or a mass flow meter adapted to generate a signal indicative of a concentration of the precursor in the process gas; and
a controller configured to calculate a mass flow rate of the precursor based on the signal.

2. The apparatus of claim 1, wherein the controller is configured to adjust both the first valve and the second valve while the precursor is pulsed into the process chamber at a period of time in a range from about 0.01 second to about 5 seconds.

3. The apparatus of claim 1, wherein the controller is configured to adjust both the first valve and the second valve while maintaining the process gas with a constant flow.

4. The apparatus of claim 1, wherein the controller is configured to adjust the temperature of the vessel to change the concentration of the precursor in the process gas.

5. The apparatus of claim 4, wherein the controller is configured to adjust the first valve and the second valve while maintaining the process gas with a constant flow.

6. The apparatus of claim 1, wherein the first valve adjusts to increase or decrease the concentration of the precursor in the process gas.

7. The apparatus of claim 6, wherein the second valve adjustes to maintain a constant flow.

8. The apparatus of claim 1, wherein the first carrier gas and the second carrier gas are the same.

9. The apparatus of claim 1, wherein the first carrier gas and the second carrier gas are selected from the group consisting of argon, nitrogen, helium, hydrogen and combinations thereof.

10. The apparatus of claim 9, wherein the precursor is selected from the group consisting of W(CO)₆, (Me₂N)₅Ta, (Et₂N)₅Ta, (^{t}BuN)Ta(NMe₂)₃, (^{t}BuN)Ta(NEt₂)₃, TaCl₅, TaF₅, TiCl₄, HfCl₄, (Et₂N)₄Hf and XeF₂.

11. A system comprising:
a process chamber;
a gas delivery system adapted to deliver a precursor from a vessel containing the precursor to the process chamber via a process gas produced by flowing a first carrier gas into the vessel and combining the first carrier gas with a second carrier gas flowing through a bypass around the vessel;
a precursor monitoring apparatus disposed between the process chamber and the vessel, wherein the precursor monitoring apparatus has a gas analyzer to generate a signal indicative of a concentration of the precursor in the process gas or the signal is indicative of the flow rate of the precursor; and
an integral controller to receive the signal.

12. The apparatus of claim 11, wherein the integral controller is configured to adjust both the process gas to be pulsed into the process chamber at a period of time in a range from about 0.01 second to about 5 seconds.

13. The system of claim 11, wherein a first valve controls the first carrier gas and a second valve controls the second carrier gas.

14. The system of claim 13, wherein the integral controller is configured to adjust both the first valve and the second valve while maintaining the process gas with a constant flow.

15. The system of claim 11, wherein the integral controller is configured to increase a temperature of the vessel to increase the concentration of the precursor.

16. The system of claim 15, wherein the integral controller is configured to adjust the first valve and the second valve while maintaining the process gas with a constant flow.

17. The system of claim 13, wherein the first valve is adjusted to increase or decrease the concentration of the precursor in the process gas.

18. The system of claim 17, wherein the second valve is adjusted to maintain a constant flow.

19. The system of claim 11, wherein the first carrier gas and the second carrier gas are the same.

20. The system of claim 11, wherein the gas analyzer is selected from the group consisting of ultrasonic transducers, infrared spectroscopy, ultraviolet spectroscopy, gas chromatography, mass spectroscopy, mass flow meters and combinations thereof.

21. The system of claim 20, wherein the first carrier gas and the second carrier gas are selected from the group consisting of argon, nitrogen, helium and hydrogen.

22. The system of claim 21, wherein the precursor is selected from the group consisting of W(CO)₆, (Me₂N)₅Ta, (Et₂N)₅Ta, (^{t}BuN)Ta(NMe₂)₃, (^{t}BuN)Ta(NEt₂)₃, TaCl₅, TaF₅, TiCl₄, HfCl₄, (Et₂N)₄Hf and XeF₂.

23. An apparatus for delivering of a precursor from a vessel to a process chamber, comprising:
a first valve to regulate a first carrier gas flowing through an input into the vessel;
an output from the vessel in fluid communication with the process chamber;
a second valve to regulate a second carrier gas flowing to the process chamber;
a process gas comprising the first carrier gas, the second carrier gas and the precursor;
a gas analyzer to generate a signal indicative of a concentration of the precursor in the process gas or indicative of a process flow rate; and
a controller to receive the signal and is configured to maintain the concentration of the precursor and the volume flow rate of the process gas constant by adjusting the first valve and the second valve.

24. The method of claim 23, wherein the precursor is pulsed into the process chamber at a period of time in a range from about 0.01 second to about 5 seconds.

25. The system of claim 23, wherein the controller is configured to increase a temperature of the vessel to increase the concentration of the precursor.

26. The system of claim 23, wherein the first valve adjusts to increase or decrease the concentration of the precursor in the process gas.

27. The system of claim 26, wherein the second valve adjusts to maintain the process gas constant.

28. The system of claim 23, wherein the first carrier gas and the second carrier gas are the same.

29. The system of claim 23, wherein a gas analyzer is selected from the group consisting of ultrasonic transducers, infrared spectroscopy, ultraviolet spectroscopy, gas chromatography, mass spectroscopy, mass flow meter and combinations thereof.

30. The system of claim 29, wherein the first carrier gas and the second carrier gas are selected from the group consisting of argon, nitrogen, helium and hydrogen.

31. The system of claim 30, wherein the precursor is selected from the group consisting of W(CO)₆, (Me₂N)₅Ta, (Et₂N)₅Ta, (^{t}BuN)Ta(NMe₂)₃, (^{t}BuN)Ta(NEt₂)₃, TaCl₅, TaF₅, TiCl₄, HfCl₄, (Et₂N)₄Hf and XeF₂.

32. A method for monitoring and controlling delivery of a precursor from a vessel to a process chamber, comprising:
measuring a concentration of the precursor in a process gas, wherein the process gas is produced by flowing a first carrier gas through the vessel and then combining with a second carrier gas; and
calculating a mass flow rate of the precursor based on the measured concentration of the precursor in the process gas, the first carrier gas flow and the second carrier gas flow.

33. The method of claim 32, wherein the precursor is pulsed into the process chamber at a period of time in a range from about 0.01 second to about 5 seconds.

34. The method of claim 32, wherein regulating the first carrier gas and the second carrier gas creates a constant flow for the process gas.

35. The method of claim 32, wherein the first carrier gas is controlled by a first valve and the second carrier gas is controlled by a second valve.

36. The method of claim 35, wherein an integral controller is configured to adjust both the first valve and the second valve while maintaining the process gas with a constant flow.

37. The method of claim 36, wherein increasing a temperature of the vessel via the integral controller increases the concentration of the precursor.

38. The method of claim 37, wherein adjusting the first valve and the second valve via the integral controller maintains the process gas with a constant flow.

39. The method of claim 32, wherein measuring the concentration of the precursor uses a gas analyzer selected from the group consisting of ultrasonic transducers, infrared spectroscopy, ultraviolet spectroscopy, gas chromatography, mass spectroscopy, mass flow meter and combinations thereof.

40. The method of claim 39, wherein the first carrier gas and the second carrier gas are selected from the group consisting of argon, nitrogen, helium and hydrogen.

41. The method of claim 40, wherein the precursor is selected from the group consisting of W(CO)₆, (Me₂N)₅Ta, (Et₂N)₅Ta, (^{t}BuN)Ta(NMe₂)₃, (^{t}BuN)Ta(NEt₂)₃, TaCl₅, TaF₅, TiCl₄, HfCl₄, (Et₂N)₄Hf and XeF₂.
